(19) United States
(12) Patent Application Publication
(10) Pub. No.: US 2007/0045871 A1
(43) Pub. Date: Mar. 1, 2007

(54) Pad open structure

(75) Inventor: Chu-Sheng Lee, Tainan City (TW)

Correspondence Address: BIRCH STEWART KOLASCH & BIRCH, PO BOX 747, FALLS CHURCH, VA, 22040-0747, US

(73) Assignee: Sitronix Technology Corp.

(21) Appl. No.: 11/209,805

(22) Filed: Aug. 24, 2005

(51) Int. Cl. H01L 23/48

(52) U.S. Cl. 257/784

(57) ABSTRACT

A pad open structure, after an insulation layer is installed at the up of the pad, the insulation layer forms plural pad opens by lithography. The insulation layer is exposed to the surface of the pad by the pad opens. The gold bump forms the upper part of the insulation layer, which forms an electric connection through the pad opens to the pad. By way of this, when the gold bump is formed at the surface of the pad opens and the surrounding insulation layer, reducing the affection produced by a single pad open that hollows the surface of the gold bump such that the gold bump has an extra flat surface.

### FIELD OF THE INVENTION

The present invention relates to a pad open structure, mainly aims to the Chip on Glass package, that makes the gold bump on a driving IC used for electric connection have an extra flat surface.

### BACKGROUND OF THE INVENTION

Compared liquid crystal displays (LCDs) with traditional CRTs, LCDs have characteristics of low-driving voltage, micro-power consumption, large-display capacity, low radiation and light, thin in size, so they are widely used in various audio-video equipments and communication equipments. Packages for the driving IC of a LCD are developed from the Chip on Board (COB) and the Tape Carrier Bounding (TAB) at early days to the Chip on Glass (COG) and Chip on Film (COF) at these days.

FIG. 1 is a schematic diagram for the bonding of the structure of a COG. The structure of a COG includes a driving IC 11, an Anisotropic Conductive Film (ACF) 12, and a glass substrate 13. There are plural gold bumps 111 on the driving IC 11, and the glass substrate 13 has plural electrodes 131 that are formed by the conductive film, and the quantity and location of electrodes 131 are correspond to the quantity and location of the gold bumps 111. The ACF 12 is composed of the binder 121 and conductive particles 122. The COG structure is conducted by way of the ACF 12 that bonds the gold bumps 111 of the driving IC 11 and the electrodes 131 on the glass substrate 13.

The bonding method for the COG structure is firstly to provide the glass substrate 13 which has plural electrodes 131 that are formed by the conductive film; to bond the ACF 12 to the glass substrate 13; and to put the driving IC 11 on the ACF 12. There are plural gold bumps 111 on the driving IC 11. The number of gold bumps 111 is corresponding to the number of electrodes 131 on the glass substrate 13 respectively. Then, do the operations of pre-bonding and main bonding to the abovementioned structure under the condition of fixed temperature, velocity, and pressure so as to actualize the electric connection between the gold bumps 111 of the driving IC 11 and the electrodes 131 on the glass substrate 13 through the conductive particles 122 of the ACF 12, and bind the driving IC 11 to the glass substrate 13 by the binder 121 (as shown in FIG. 2).

The main characteristic of the ACF 12 is that it has electric conduction in the direction of z-axis whereas it is not conductive in the horizontal direction. Hence, when the conductive particles 122 are small enough or insulated among each other adequately, the fine pitch binding effect among the gold bumps 111 can be achieved.

Because LCDs are required for higher resolution, pins of the driving IC 11 become more and more. In other words, not only the integration extent is higher and higher but also the number of the gold bumps 111 is more and more.

Accordingly, for the purpose of reducing the space occupied by the pitches among the gold bumps 111, except the layout consideration for those electric connection wires, reducing the pitches among the gold bumps 111 is another way for designers to work on. Because if the pitches among the gold bumps 111 cannot be reduced effectively, the goal for reducing the chip dimension is limited.

However, the range for the diameter of common conductive particles 122 is 3˜15 μm. Too large conductive particles 122 reduce the number of contacting particles of each electrode, and the shorted situation 14 (as shown in FIG. 3) between the neighboring electrodes due to the contact of the conductive particles 122 is easily happened. Similarly, after reducing the pitches among the gold bumps 111, the abovementioned problems also occur. As a result, to obtain fine pitches, small-diameter conductive particles 122 such as 3˜4 μm in diameter have to be adopted.

However, the schematic diagram for the electric pad of the driving IC 11 as shown in FIG. 4 shows that the pad 112 on the driving IC 11 forms a pad open 114 by the lithography through the insulation layer 113 (please refer to FIG. 5), and then forms a gold bump 111 with thickness 15˜17 μm approximately by the electro-plating.

In the bond between the common standard gold bumps 111 and the electrode 131 of the glass substrate 13, more than five conductive particles 122 will be broken. The reason is that the gold bump 111 is formed at the surface of the pad open 114 and the surrounding insulation layer 113, so the surface 1141 of the gold bump 111 will form a surface configuration that hollows approximately 2 μm due to the thickness of the insulation layer 113 when the surface area of the common gold bump 111 is approximate 2000 m². During electroplating, a ±1 μm plating difference occurs on the same surface due to the manufacturing process.

To sum up, the drop height between the highest and the lowest surface 1141 of the gold bump 111 will be 4 μm. Therefore, because of the drop height of the surface 1141 that will not break conductive particles 122 enough, the contacting area between the small-diameter conductive particles 122 with 3˜4 μm in diameter and the gold bump 111 is not enough such that the electric connection effect is not good.

### SUMMARY OF THE INVENTION

Consequently, the main purpose of the current invention is to solve the flattening problem for the surfaces of the gold bumps on the driving IC. By flattening the surfaces of the gold bumps, the small-diameter conductive particles are bonded but not broken enough so that the problems of insufficient contact area won't occur. During the bonding process of the COG, the electric connection effects among the connecting electrodes are good.

Another purpose of the current invention is that for any driving IC used in the COG package can adopt the ACF with small-diameter conductive particles to achieve the goal of reducing fine pitches among gold bumps without changing manufacturing process. By way of this, the integration extent of the circuit on the driving IC can be increased. This invention is a pad open structure, which is used as the connecting pad to the outside. After the insulation layer is installed at the surface of the pad, the insulation layer forms plural pad opens by lithography. The pad opens small area surfaces of the pad are exposed by pad opens. The gold bump forms the upper part of the insulation layer, which forms an electric connection through the pad opens to the pad.

The present invention changes the original structure of large area pad opens to plural pad opens. By adjusting the ratio between areas of the pad opens and the unopened region with the insulation layer and under the consideration of electric connection, when the gold bump is formed at the surface of the pad open and the surrounding insulation layer, because the single area of the pad opens is not large so as to reduce the affection produced by a well-known single large area pad open that hollows the surface of the gold bump seriously such that the gold bump of this invention has an extra flat surface.

### BRIEF DESCRIPTION FOR THE DRAWINGS

FIG. 1 is the schematic diagram for the bonding of the structure of a COG of the previous technology.

FIG. 2 is the schematic diagram for a COG package.

FIG. 3 is the schematic diagram for the shorted situation due to conductive particles contact.

FIG. 4 is the schematic diagram for the well-known electric pad of the driving IC.

FIG. 5 is the schematic diagram for the structure of the pad open shown in FIG. 4.

FIG. 6 is the schematic diagram for the COG package of the present invention.

FIG. 7 is the schematic diagram for the electric pad of the driving IC of the present invention.

FIG. 8 is the schematic diagram for the structure of the pad open shown in FIG. 7.

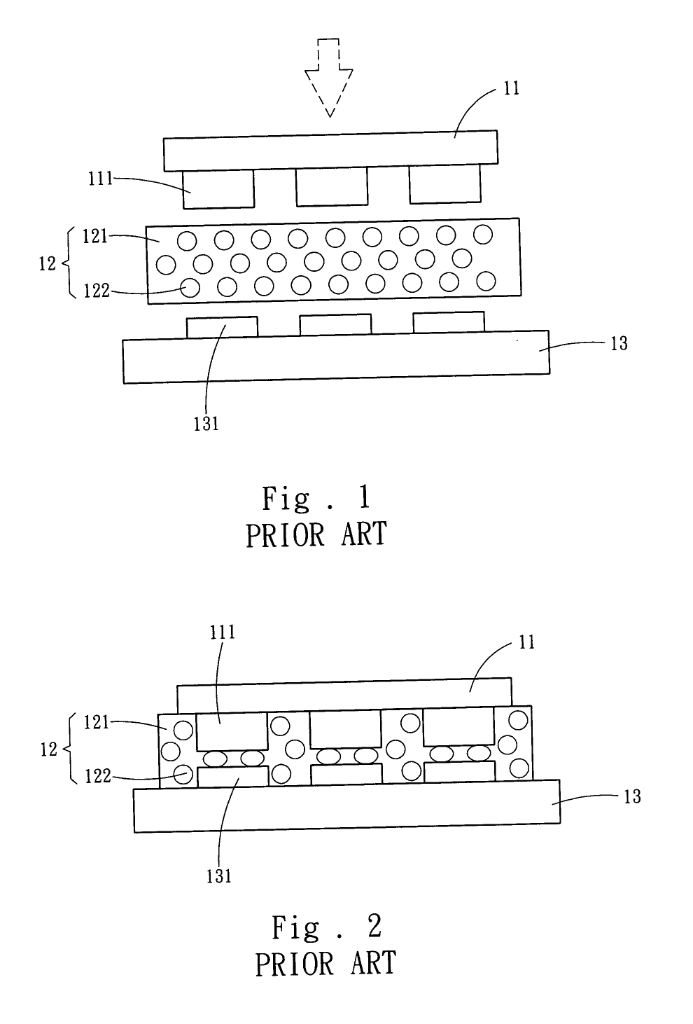

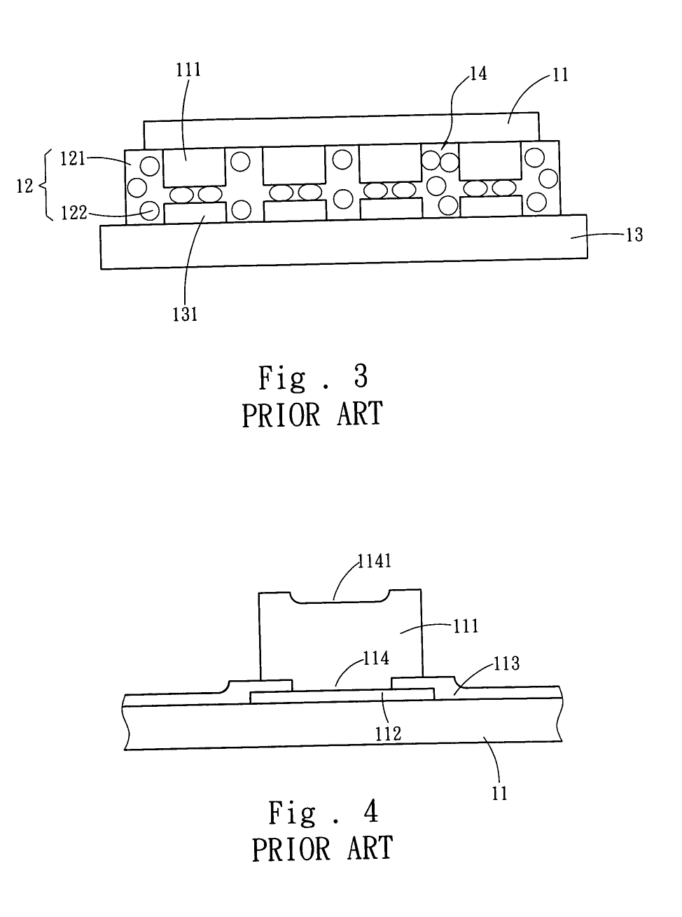

### DETAILED DESCRIPTION OF THE PREFERRED EMBODIMENTS

The detailed descriptions for content and technology of this invention associated with figures are as follows.

FIG. 6 is the schematic diagram for the COG package of the present invention. The structure of a COG includes a driving IC 21 having plural gold bumps 211, a glass substrate 23 having plural electrodes 231 that are formed by conductive film and the quantity and location of electrodes 231 are corresponding to the quantity and location of the gold bumps 211, and an Anisotropic Conductive Film (ACF) 22 which is composed of the binder 221 and small-diameter conductive particles 222 with 3˜4 μm diameter. The COG actualizes the electric connection between the gold bumps 211 of the driving IC 21 and the electrodes 231 on the glass substrate 23 through the conductive particles 222, and binds the driving IC 21 to the glass substrate 23 by the binder 221.

This invention is mainly a pad open structure, which aims to improve the electric pad structure of the driving IC 21. The situation for the conductive particles 222 which is bonded but not broken enough won't occur during the bonding process of the COG.

The contact areas between the gold bumps 211 and the electrodes 231 on the glass substrate 23 are sufficient and the electric connection effect is good.

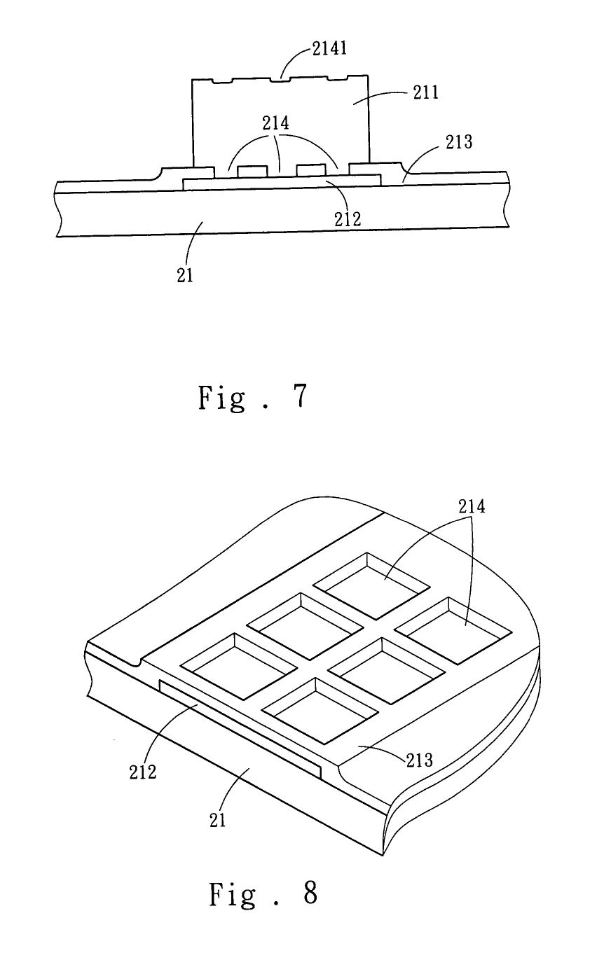

FIG. 7 is the schematic diagram for the electric pad of the driving IC 21. The driving IC 21 installs the pad 212 that is used as the connecting pad to the outside. The insulation layer 213 is installed at the surface of the pad 212, and the insulation layer 213 forms plural small-area pad opens 214 by lithography. The insulation layer 213 is exposed to the surface of the pad 212 by the pad opens 214 (please further refer to FIG. 8). In which the pad opens 214 are not connected between each other and the total area of the pad opens 214 should make it be the standard electric connection between the gold bumps 211 and the electrodes 231.

The gold bump 211 forms on the top of the insulation layer 213 and an electric connection through the pad opens 214 and the pad 212. The material of the gold bump 211 can be copper, nickel, gold, or a Sn—Pb alloy, which is formed by electroplating with thickness between 15˜18 μm.

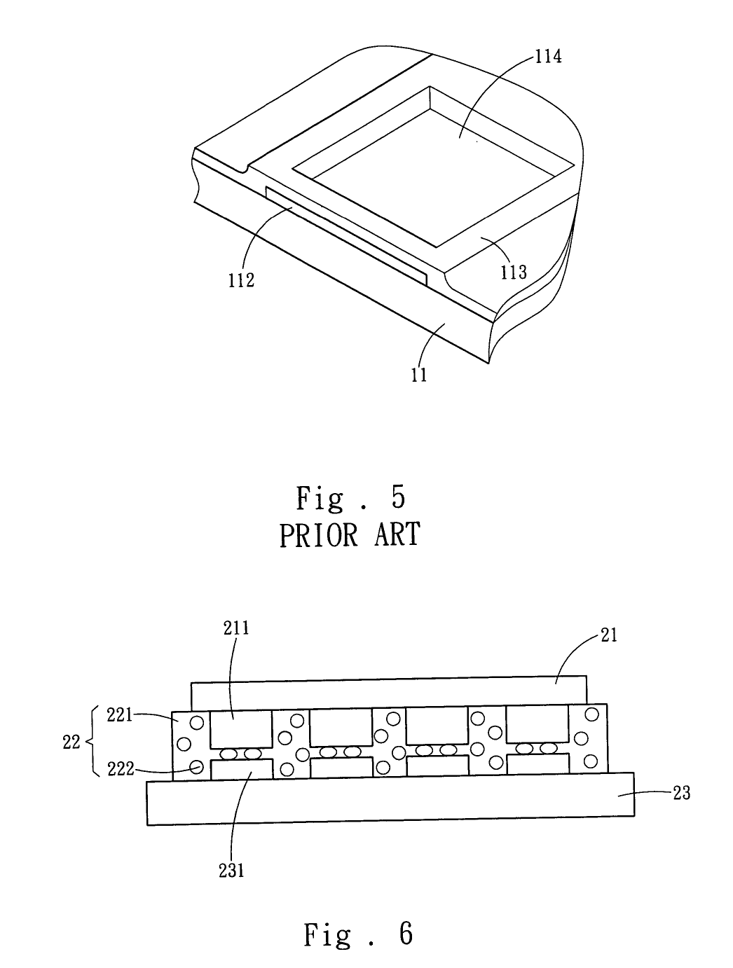

The characteristic of present invention is that this invention changes the well-known original structure of large-area pad opens 114 (as shown in FIG. 5) to plural small-area pad opens 214 (as shown in FIG. 8). Because the affection of hollowing the surface 2141 of the gold bump 211 by the thickness of the surrounding insulation layer 213 of a single small-area pad open 214 is less than 1 μm and a ±1 μm plating difference occurs on the same surface due to the electro-plating process, the drop height between the highest and the lowest surface 2141 of the gold bump 211 is less than 2 μm when the gold bump 211 is formed at the surface of the pad opens 214 and the surrounding insulation layer 213. In other words, the surface 2141 of the gold bump 211 is extra flat.

This invention improves the well-known hollowing phenomenon by substituting plural pad opens 214 for the well-known single pad open 114. However, the upper surface of the unopened insulation layer 213 is still a plane configuration. Under the principle of that there is industry-standard electric connection between the gold bump 211 and the electrode 231 and by adjusting the ratio between areas of the total opens (the area of the plural pad opens 214) and unopened region with the insulation layer 213, both the electric connection between the gold bump 211 and the electrode 231 and improving the flattening for the surface 2141 of the gold bump 211 can be achieved.

Regarding the common industry standard, more than five conductive particles 222 are broken between the gold bump 211 and the electrode 231 of the glass substrate 23 can be counted as a good effect of electric connection with sufficient contacting area. Consequently, for the electric pad formed in the driving IC 21 of this invention, the surface 2141 of the gold bump 211 becomes extra flat due to the plural small-area pad opens 214. As a result, when the conductive particles 222 are small-diameter with diameter 3˜4 μm, the well-known problem that small-diameter conductive particles 222 are bonded but not broken enough so that the problems of insufficient contact area won't occur. During the bonding process of the COG, the electric connection effects among the connecting electrodes are good.

Because the aforementioned breaking problem for the small-diameter conductive particles 222 is solved through the electric pad structure of this invention, the pitch between each gold bump 211 should be greater than three times of the diameter of the conductive particle 222 according to the industry standard. In other words, this invention can adopt the ACF 22 with small-diameter conductive particles 222. Take the conductive particle 222 with diameter 3 μm as an example; the pitch between each gold bump 211 can be reduced to 10 μm, i.e. the goal of fine pitch is achieved. The integration extent of the circuit on the driving IC can be increased at the same time.

However, the above description is only a better practice example for the current invention, which is not used to limit the practice scope of the invention. All equivalent changes and modifications based on the claimed items of this invention are in the scope of the present invention.

What is claimed is:

1. A pad open structure, which is used on the driving IC for the Chip on Glass package, comprising:
a pad being on the driving IC;
an insulation layer being formed on the surface of the pad, forming plural small-area pad opens by lithography, and the insulation layer being exposed to the surface of the pad by the pad opens; and
a gold bump being formed on the surface of the insulation layer, and having an electric connection through the pad opens to the pad.

2. The pad open structure of claim 1, wherein the pad opens are not connected between each other, and the total area of the pad opens should make it be the standard electric connection between the gold bump and the corresponding electrode on the glass substrate.

3. The pad open structure of claim 1, wherein the gold bump is manufactured by electroplating.

4. The pad open structure of claim 1, wherein the gold bump can be selected from the group of copper, nickel, and gold.

5. The pad open structure of claim 1, wherein the gold bump is a Sn—Pb alloy.

6. The pad open structure of claim 1, wherein the thickness of the gold bump is between 15˜18 μm.
